(19) United States
(12) Patent Application Publication
(10) Pub. No.: US 2006/0203436 A1
(43) Pub. Date: Sep. 14, 2006

(54) Monitor apparatus

(76) Inventors: Kwang-sung Hwang, Suwon-si (KR); Young-tai Kim, Yongin-si (KR)

Correspondence Address: STANZIONE & KIM, LLP, 919 18TH STREET, N.W., SUITE 440, WASHINGTON, DC, 20006, US

(21) Appl. No.: 11/354,954

(22) Filed: Feb. 16, 2006

(30) Foreign Application Priority Data
Mar. 8, 2005 (KR) 2005-19345

(51) Int. Cl. H05K 5/00; H05K 7/00

(52) U.S. Cl. 361/679

(57) ABSTRACT

A monitor apparatus includes a main body to display an image, a base to support the main body, a cable unit having a cable extending from the main body through the base to supply a signal to the main body, and a cable port provided at an end of the main body cable to receive the signal from and external source, and a power switch provided at the base and coupled with the cable unit to control a supply of power to the main body.

### CROSS-REFERENCE TO RELATED APPLICATIONS

This application claims the benefit under 35 U.S.C. § 119 of Korean Patent Application No. 10-2005-19345, filed on Mar. 8, 2005, the disclosure of which is incorporated herein in its entirety.

### BACKGROUND OF THE INVENTION

1. Field of the Invention

The present general inventive concept relates to a monitor apparatus, and more particularly, to a monitor apparatus having an improved structure that includes a base and a rotating structure of a monitor main body.

2. Description of the Related Art

Conventional monitor apparatuses typically have a monitor, e.g., a main body, having an image displayed thereon, and a base arranged on an installation surface, such as a table, to support the monitor main body.

The monitor main body may be a cathode ray tube (CRT) display or a thin display panel, such as a liquid crystal display (LCD) and a plasma display panel (PDP).

A conventional monitor apparatus having a thin display panel is disclosed in Korean Patent First Publication No. 2002-27683. Here, the conventional monitor apparatus includes a monitor main body, a base member supporting the monitor main body, a link member provided between the monitor main body and the base member, a base hinge to rotatably connect a first end of the link member and the base member to tilt the link member with respect to a plate of the base member, a monitor hinge spaced apart from the base hinge to rotatably connect a second end of the link member and the monitor main body, and an auxiliary link member to transfer a rotation of the link member with respect to the base member to a rotation of the monitor main body. Therefore, the monitor main body of the conventional monitor apparatus is capable of simultaneously tilting about a tilting axis of a horizontal direction with respect to the base member and adjusting a height thereof with respect to the base member.

However, the structure of the conventional monitor apparatus is complicated because the conventional monitor apparatus generally includes a power switch in the monitor main body, which makes it difficult to reduce a size of the monitor main body.

### SUMMARY OF THE INVENTION

The present general inventive concept provides a monitor apparatus having a simplified structure of a monitor main body to reduce a size thereof.

The present general inventive concept also provides a monitor apparatus having a monitor main body that is capable of rotating in various directions.

Additional aspects and utilities of the present general inventive concept will be set forth in the description which follows, and in part, will be apparent from the description, or may be learned by practice of the present general inventive concept.

The foregoing and/or other aspects of the present general inventive concept are achieved by providing a monitor apparatus, including a main body to display an image thereon, a support part to support the main body, a base coupled with the support part, a cable unit having a cable extending from the main body through the base to transmit a signal to the main body and a cable port provided at an end of the cable to receive the signal, and a power switch provided at the base and connected with the cable unit to control a supply of power to the main body.

The monitor apparatus may further include a swivel unit provided at the base to rotate the main body about a vertical axis relative to the base.

The swivel unit may include a swivel member coupled with the main body, and a swivel supporter to support the swivel member and enable the swivel member to rotate with respect to the base.

The swivel supporter may be provided at the base to couple with the swivel member, and supports and attaches a center portion of the swivel member with the base to enable the swivel member to rotate with respect to the base.

The swivel unit may further include a swivel angle adjuster to adjust a swivel angle of the main body, and wherein the swivel angel adjuster comprises a projection extending from one of the swivel member and the swivel supporter to the other one of the swivel member and the swivel supporter, and a projection guider provided at the other one of the swivel member and the swivel supporter to guide the projection in a predetermined angel range.

The monitor apparatus may further include an external terminal connector provided at the base to connect with the cable unit and selectively connect with an external terminal.

The cable unit may extend from the base such that the cable port is spaced apart from the base, and the cable unit further comprises a port housing to support the cable port which is spaced apart from the base.

The support part may include a link member provided between the main body and the base, and a base hinge provided between the link member and the base to tilt about an axis extending in a horizontal direction with respect to the base, wherein the base hinge comprises a base bracket coupled with the swivel member, and a base hinge shaft to connect the link member with the base bracket such that the link member tilts with respect to the base bracket.

The foregoing and/or other aspects of the present general inventive concept are also achieved by providing a monitor apparatus, including a main body to display an image thereon, a support part to support the mail body, a base coupled with the support part, a power cable extending from the base to receive power from an external source, a connecting cable extending from the main body to the base to connect with the power cable to supply the power to the main body, and a power switch provided at the base and connected to the connecting cable to control the supply of the power to the main body.

The monitor apparatus may further include a swivel unit disposed between the support part and the base to swivel the support part with respect to the base about a vertical axis extending from the base.

The monitor apparatus may further include a tilting unit disposed between the main body and the support par to tilt the main body with respect to the base about an axis extending in a horizontal direction of the base.

The base may further include an upper cover, a lower cover, and an interior portion between the upper and lower covers, and the connecting cable extends from the main body into the interior portion of the base and connects with the power cable and the power switch in the interior portion of the base.

The foregoing and/or other aspects of the present general inventive concept are also achieved by providing a monitor apparatus, including a main body to display an image thereon, a support part to support the main body; a base coupled with the support part, and a power switch provided at the base control a supply of power to the main body.

The monitor apparatus may include a cable unit extending from the main body through the base, and protruding from the base to connect to an external power source to supply power to the main body.

The power switch may be connected to the cable unit within the base to control the power supplied to the main body through the cable unit.

The cable unit may include a cable port to connect to an external apparatus to receive an image signal to display on the main body and to receive the power to be supplied to the main body.

The monitor apparatus may further include an external terminal connector provided in the base, connected between the power switch and the cable unit, and including at least one connecting port exposed through a surface of the base to connect with terminals of an external apparatus to receive an image signal to be displayed on the main body.

The image signal received by the connecting port can be transmitted to the main body through the cable unit.

The monitor apparatus may further include a coupling unit to couple the main body to the base, including a swivel unit provided between the base and the main body to swivel the main body with respect to the base, and a link member coupled at one end to the main body and tiltably coupled at the other end to the swivel unit to tilt the main body with respect to the base.

### BRIEF DESCRIPTION OF THE DRAWINGS

These and/or other aspects of the present general inventive concept will become apparent and more readily appreciated from the following description of the embodiments, taken in conjunction with the accompanying drawings of which.

FIG. 1 is a perspective view illustrating a monitor apparatus according to an embodiment of the present general inventive concept.

FIG. 2 and FIG. 3 are partially exploded views illustrating the monitor apparatus of FIG. 1.

FIG. 4 is a perspective view illustrating operations of the monitor apparatus of FIG. 1.

### DESCRIPTION OF THE ILLUSTRATED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

It is understood that when an element or layer is referred to as being “on” or “connected to” or “connected with” another element or layer, it can be directly on or indirectly connected to or with the other element or layer, or intervening elements or layers may be present.

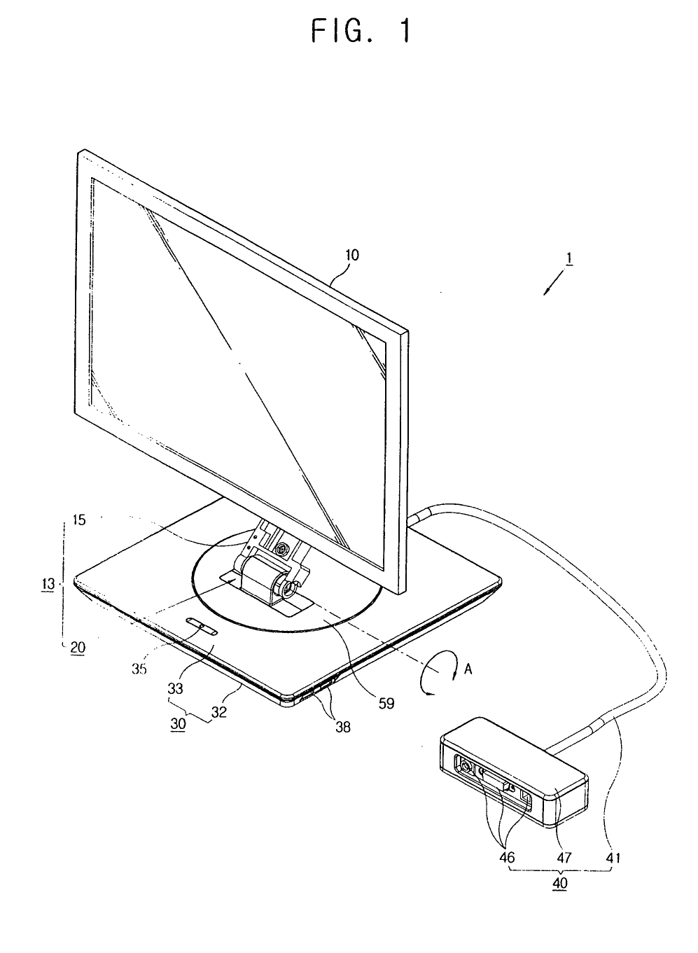

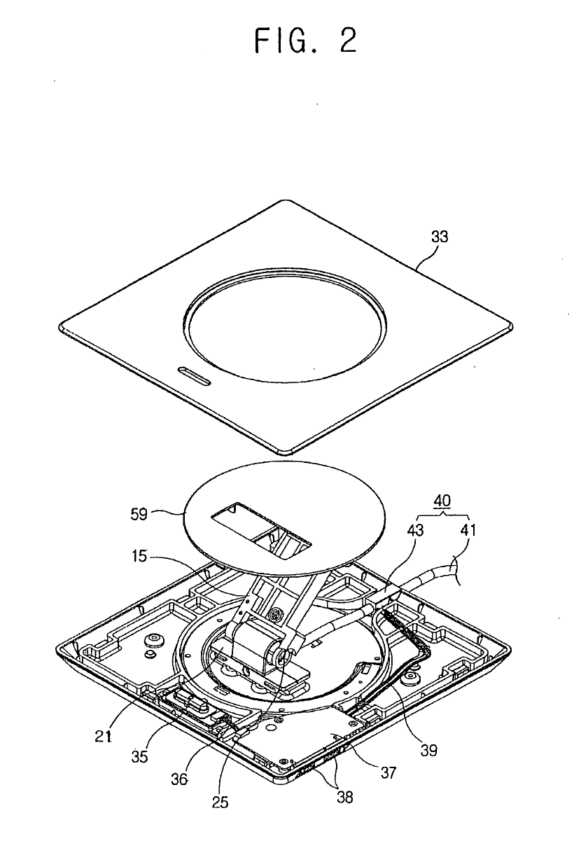

FIGS. 1-4 illustrate a monitor apparatus 1 according to an embodiment of the present general inventive concept. Referring to FIGS. 1-4, the monitor apparatus 1 includes a main body 10, e.g., a monitor to display an image thereon, a base 30 to support the main body 10 against an installation surface, a cable unit 40 having a main body cable 41 extending from the main body 10 through the base 30 to transmit a signal, e.g., an electric signal, to the main body 10, and a cable port 46 provided at a terminal of the main body cable 41 to receive the signal from an external source, and an power switch 35 provided at the base 30 and coupled with the cable unit 40 to control a supply of power to the main body 10.

The monitor apparatus 1 further includes a swivel unit 50 provided at the base 30 to swivel, turn or rotate the main body 10 about a swiveling axis (B) extending in a vertical direction with respect to the base 30. The monitor apparatus 1 may further include a support part 13 to support the main body 10. The support part 13 can include a link member 15 provided between the main body 10 and the base 30, and a base hinge 20 provided between the link member 15 and the base 30 to tilt the link member 15 about a tilting axis (A) extending in a horizontal direction with respect to the base 30.

The main body 10 may be a thin display panel, such as a liquid crystal display (LCD) a plasma display panel (PDP), and the like, or a cathode ray tube (CRT) type display. The main body 10 is coupled with the link member 15 as described below.

The link member 15 can have a plate-like shape, wherein a first side thereof is coupled with a rear surface of the main body 10, and a second side thereof is coupled with the base hinge 20. The first side of the link member 15 may be coupled with the rear surface of the main body 10 to tilt about the titling axis (A). The second side of the link member 15 is coupled with a base bracket 21 of the base hinge 20 and tilts about a base hinge shaft 25 (to be described later).

The base hinge 20 includes the base bracket 21, which is coupled with the base 30, and the base hinge shaft 25 to tiltably couple the link member 15 with the base bracket 21 so that the link member 15 is tiltable with respect to the base bracket 21.

The base bracket 21 may be coupled with a swivel member 51 (to be described later) of the swivel unit 50 by a fastening device, such as screw. Accordingly, the main body 10 may tilt with respect to the base bracket 21 and may swivel with respect to the base 30 with the base bracket 21, which is coupled with the link member 15.

The base 30 may have a plate-like shape and may be mounted or attached on an installation surface, such a table. The base 30 includes an external terminal connector 37 connected with the cable unit 40 to input a signal that is selectively supplied from an external source. The base 30 includes a base frame 31 to support the swivel unit 50 and an upper cover 33 and a lower cover 32 disposed at an upper portion of the base frame 31 and a lower portion of the base frame 31, respectively.

As illustrated in FIG. 1, the power switch 35 may be exposed through the upper cover 33 of the base 30 and be attached or coupled with the base frame 31. For example, the power switch 35 may be arranged at a front area of the base 30, e.g., in front of a display side of the main body 10, such that the power switch 35 may be easily operated and readily accessible by a user. The power switch 35 is connected with the cable unit 40 by a power cable 36 or the like. As illustrated in FIG. 1, the power switch 35 may be connected with the cable unit 40 through the external terminal connector 37. The power switch 35 supplies and interrupts power supplied to the cable port 46 from an external source, thereby controlling the supply of power to the main body 10. Accordingly, the user may operate the power switch 35 and turn power to the main body 10 on or off.

The external terminal connector 37 is coupled with the base frame 31 and exposed through the upper cover 33 of the base 30 and/or the lower cover 32 of the base 30. At least one connecting port 38 is provided in the external terminal connector 37 to be detachably coupled with an external terminal (not shown) to send signals thereto and to receive signals therefrom. For example, the connecting port 38 may be a universal service bus (USB) connector. The external terminal connector 37 is connected with the cable unit 40 by the connecting cable 39. Accordingly, when the external terminal is coupled with the connecting port 38, the signals received from the external terminal may be displayed or the signals may be transmitted to the external terminal. As illustrating in FIG. 1, the connecting port 38 may be disposed at a lateral front area of the base 30 to be easily accessible to a user.

The cable unit 40 includes the main body cable 41 and the cable port 46, as descried above.

The main body cable 41 extends from the main body 10 through the base 30 and is mounted or attached between the upper cover 33 and the lower cover 32. The main body cable 41 is supported by the link member 15 and the base hinge 20 to be connected between the main body 10 and the base 30.

A cable holder 43 is provided at a portion of the main body cable 41 to hold the main body cable 41 in place relative to the base 10.

The cable holder 43 is coupled with a holder accommodator 45 provided in the base 30 such that the portion of the main body cable 41 at which the cable holder 43 is provided is not exposed externally of the base 30.

The cable port 46 is provided at the terminal of the main body cable 41 and can connect with an external terminal that transmits an image signal and the electric power to the main body 10. Accordingly, the main body cable 41 can extend externally from the base 30 to connect with the external terminal. The cable port 46 can connect with the external terminal, and may transmit and receive various types of signals in addition to the image signal and the electric power. The cable port 46 can be spaced apart from the base 30 and is supported by a port housing 47, as illustrated in FIG. 1. According to another embodiment of the present general inventive concept, the cable port 46 may be mounted or attached to the base 30.

The base frame 31 can have a substantially plate-like shape. The base frame 31 may be made of a metallic or non-metallic material, e.g., a plastic material, having a substantially suitable strength. The base frame 31 is coupled with the power switch 35 and the external terminal connector 37 by a fastener, such as a screw and the like, to support the power switch 35 and the external terminal connector 37.

The swivel unit 50 includes the swivel member 51 that is coupled with the main body 10 through the link member 15, and a swivel supporter 55 to swivelably or rotatably support the swivel member 51 with respect to the base 30. The swivel unit 50 further includes a swivel angle adjuster 61 that adjusts a swivel angle of the main body 10.

The swivel member 51 is disposed on the swivel supporter 55, and may have a substantially disc-like shape to swivel about the swiveling axis (B) with respect to the swivel supporter 55. The swivel member 51 may include a base bracket fastener 52 fastened to the base bracket 21 by a fastener, such as a screw and the like, and a swivel supporter fastener 53 fastened to the swivel supporter 55 by a fastening screw 57 in a substantially center area of the swivel member 51 that is substantially centered about the swiveling axis (B). A swivel member cover 59 is provided at an upper side of the swivel member 51, and has a penetrating portion to be penetrated by the base bracket 21.

The swivel supporter 55 accommodates and supports the swivel member 51. The swivel supporter 55 includes a swivel member fastener 56 that is swivelably or rotatably fastened to the fastening screw 57 of the swivel member 51.

The swivel angle adjuster 61 includes a projection 63 extending from one of the swivel member 51 and the swivel supporter 55 to the other one thereof, and a projection guider 65 provided at the other one of the swivel member 51 and the swivel supporter 55 to guide the projection 63 at a predetermined angle range.

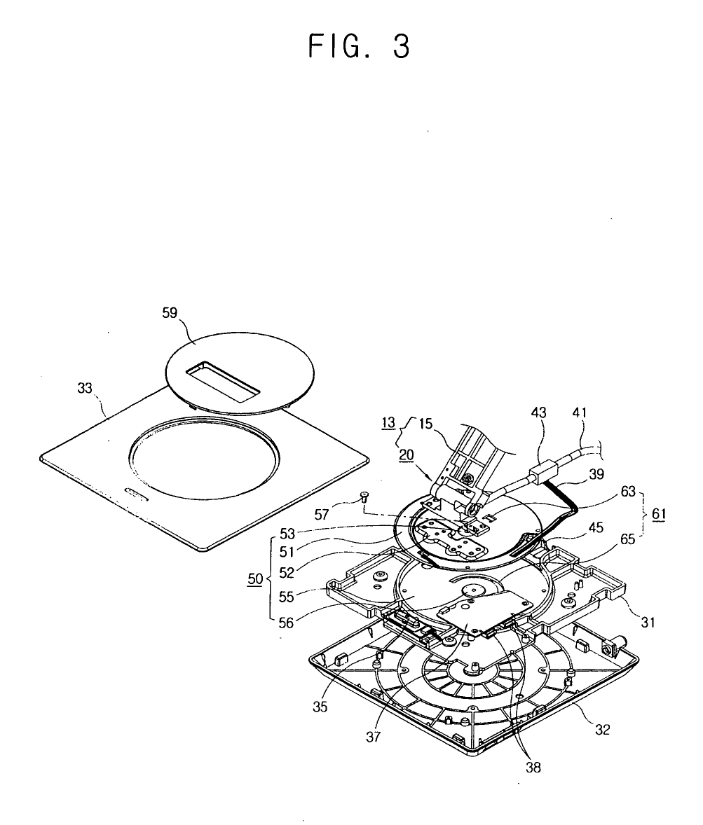

The projection 63 can project substantially vertically from the one of the swivel member 51 and the swivel supporter 55 toward the other one thereof. For example, the projection can project downwardly from the swivel member 51 toward the swivel supporter 55, as illustrated in FIG. 3. The projection guider 65 may be curved. For example, the projection guider 65 can be formed as an arc shape in a portion of the swivel supporter 55 to accommodate the projection 63, as illustrated in FIG. 3. As illustrated in FIG. 3, the projection guider 65 allows the projection 63 to rotate with respect to the fastening screw 57 in approximately a 180 degree angle range. However the present general inventive concept is not limited thereto, and the projection guider 65 may instead allow the projection 63 to rotate with respect to the fastening screw 57 in approximately a 90 degree angle range or a 360 degree angle range.

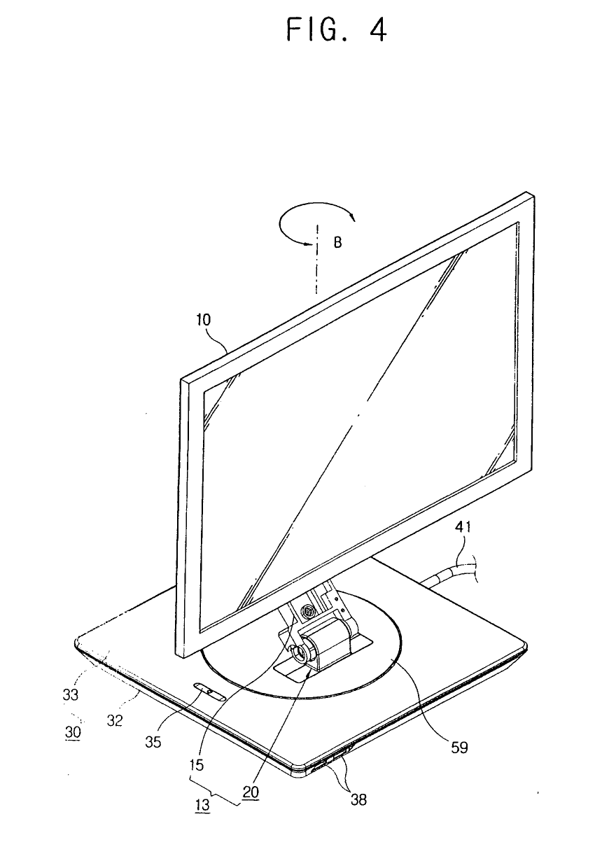

Operations of the monitor apparatus having to the above described configuration according to an embodiment of the present general inventive concept are described below while referring to FIG. 4.

Referring to FIG. 4, when the main body 10 swivels or rotates about the fastening screw 57 used as the swiveling axis (B), the main body 10 swivels with respect to the base 30 within the predetermined angle. For example, the predetermined angle range may be approximately 180 degrees.

As described above, a monitor apparatus according to an embodiment of the present general inventive concept includes a swivel unit so that a main body may be swiveled or rotated.

Furthermore, according to an embodiment of the present general inventive concept, a power switch of a main body of a monitor apparatus may be provided in a base, which simplifies the structure of the main body and reduces the size of the main body.

As described above, a cable port of a monitor apparatus may be coupled with a main body and spaced apart from a base such that a connector of an external apparatus connected thereto is not exposed.

Furthermore, an external terminal connector of a monitor apparatus can selectively connect an external terminal to a base of the monitor apparatus.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A monitor apparatus, comprising:
a main body to display an image thereon;
a support part to support the main body;
a base coupled with the support part;
a cable unit having a cable extending from the main body through the base to transmit a signal to the main body, and a cable port provided at an end of the cable to receive the signal; and
a power switch provided at the base and connected with the cable unit to control a supply of power to the main body.

2. The monitor apparatus of claim 1, further comprising a swivel unit provided at the base to rotate the main body about a vertical axis relative to the base.

3. The monitor apparatus of claim 2, wherein the swivel unit comprises:
a swivel member coupled with the main body; and
a swivel supporter to support the swivel member and enable the swivel member to rotate with respect to the base.

4. The monitor apparatus of claim 3, wherein the swivel supporter is provided at the base to couple with the swivel member, and supports and attaches a center portion of the swivel member with the base to enable the swivel member to rotate with respect to the base.

5. The monitor apparatus of claim 4, wherein the swivel unit further comprises:
a swivel angle adjuster to adjust a swivel angle of the main body, and
wherein the swivel angel adjuster comprises a projection extending from one of the swivel member and the swivel supporter to the other one of the swivel member and the swivel supporter, and a projection guider provided at the other one of the swivel member and the swivel supporter to guide the projection in a predetermined angel range.

6. The monitor apparatus of claim 1, further comprising an external terminal connector provided at the base to connect with the cable unit and selectively connect with an external terminal.

7. The monitor apparatus of claim 6, wherein the cable unit extends from the base such that the cable port is spaced apart from the base, and the cable unit further comprises a port housing to support the cable port which is spaced apart from the base.

8. The monitor apparatus of claim 3, wherein the support part comprises:
a link member provided between the main body and the base; and
a base hinge provided between the link member and the base to tilt about an axis extending in a horizontal direction with respect to the base;
wherein the base hinge comprises a base bracket coupled with the swivel member, and a base hinge shaft to connect the link member with the base bracket such that the link member tilts with respect to the base bracket.

9. A monitor apparatus, comprising:
a main body to display an image thereon;
a support part to support the main body; a base coupled with the support part;
a power cable extending from the base to receive power from an external source;
a connecting cable extending from the main body to the base to connect with the power cable to supply the power to the main body; and
a power switch provided at the base and connected to the connecting cable to control the supply of the power to the main body.

10. The monitor apparatus of claim 9, further comprising:
a swiveling unit disposed between the support part and the base to swivel the support part with respect to the base about a vertical axis extending from the base.

11. The monitor apparatus of claim 9, further comprising:
a tilting unit disposed between the main body and the support part to tilt the main body with respect to the base about an axis extending in a horizontal direction of the base.

12. The monitor apparatus of claim 9, wherein the base comprises an upper cover, a lower cover, and an interior portion between the upper and lower covers, and the connecting cable extends from the main body into the interior portion of the base and connects with the power cable and the power switch in the interior portion of the base.

13. A monitor apparatus, comprising:
a main body to display an image thereon;
a support part to support the mail body;
a base coupled with the support part; and
a power switch provided at the base to control a supply of power to the main body.

14. The monitor apparatus of claim 13, further comprising:
a cable unit extending from the main body through the base, and protruding from the base to connect to an external power source to supply power to the main body.

15. The monitor apparatus of claim 14, wherein the power switch is connected to the cable unit within the base to control the power supplied to the main body through the cable unit.

16. The monitor apparatus of claim 15, wherein the cable unit comprises a cable port to connect to an external apparatus to receive an image signal to display on the main body and to receive the power to be supplied to the main body.

17. The monitor apparatus of claim 15, further comprising:
an external terminal connector provided in the base, connected between the power switch and the cable unit, and including at least one connecting port exposed through a surface of the base to connect with terminals of an external apparatus to receive an image signal to be displayed on the main body.

18. The monitor apparatus of claim 17, wherein the image signal received by the connecting port is transmitted to the main body through the cable unit.

19. The monitor apparatus of claim 13, further comprising:
a coupling unit to couple the main body to the base, including a swivel unit provided between the base and the main body to swivel the main body with respect to the base, and a link member coupled at one end to the main body and tiltably coupled at the other end to the swivel unit to tilt the main body with respect to the base.
